(19) United States
(12) Patent Application Publication
(10) Pub. No.: US 2026/0032818 A1
(43) Pub. Date: Jan. 29, 2026

(54) RESIN MULTILAYER SUBSTRATE AND CIRCUIT MODULE

(71) Applicant: Murata Manufacturing Co., Ltd., Nagaokakyo-shi (JP)

(72) Inventors: Yukiya HIRAOKA, Nagaokakyo-shi (JP); Yoshitomo TANAKA, Nagaokakyo-shi (JP); Kazuhiro YAMAJI, Nagaokakyo-shi (JP); Tomohiro FURUMURA, Nagaokakyo-shi (JP); Katsuro HIRAYAMA, Nagaokakyo-shi (JP); Naoki NAKAYAMA, Nagaokakyo-shi (JP)

(21) Appl. No.: 19/343,274

(22) Filed: Sep. 29, 2025

Related U.S. Application Data
(63) Continuation of application No. PCT/JP2024/014345, filed on Apr. 9, 2024.

(30) Foreign Application Priority Data
Apr. 20, 2023 (JP) 2023-069293

(51) Int. Cl. H05K 1/11; H05K 1/18

(52) U.S. Cl. CPC H05K 1/115; H05K 1/181; H05K 2201/0338; H05K 2201/09536; H05K 2201/09863

(57) ABSTRACT

A resin multilayer substrate includes a resin insulating layer, first and second conductor layers, and an interlayer connection conductor penetrating the resin insulating layer in a stacking direction of the first and second conductor layers and connecting the first and second conductor layers. The interlayer connection conductor includes first and second portions. The first portion has lower conductivity than the second portion. The first conductor layer is not in contact with the second portion. The second conductor layer is in contact with the second portion. A distance between two corner portions at which a distal end portion of the second portion is most separated is longer than a distance between two corner portions at which a proximal end portion of the second portion is in contact with the second conductor layer.

### CROSS REFERENCE TO RELATED APPLICATIONS

This application claims the benefit of priority to Japanese Patent Application No. 2023-069293 filed on Apr. 20, 2023 and is a Continuation Application of PCT Application No. PCT/JP2024/014345 filed on Apr. 9, 2024. The entire contents of each application are hereby incorporated herein by reference.

### BACKGROUND OF THE INVENTION

### 1. Field of the Invention

The present invention relates to resin multilayer substrates and circuit modules.

### 2. Description of the Related Art

JP 2019-80034 A discloses a printed circuit board including a first insulating layer, a plated via extending through the first insulating layer, a second insulating layer stacked on the first insulating layer, and a paste via extending through the second insulating layer so as to be in contact with the plated via, in which a contact interface between the plated via and the paste via is located in the first insulating layer.

In the printed circuit board described in JP 2019-80034 A, by providing the contact interface between the plated via and the paste via in the first insulating layer, the connectivity between the plated via and the paste via can be improved. Here, the plated via means, for example, a film grown by a liquid phase method or a gas phase method, and the paste via means, for example, a paste solidified.

However, in a configuration in which portions having different conductivities, such as a paste via and a plated via, are mixed as an interlayer connection conductor in the insulating layer, there is a problem that the connectivity at the boundary surface between the two portions is weak and the strength of the interlayer connection conductor is not sufficient.

### SUMMARY OF THE INVENTION

Example embodiments of the present invention provide resin multilayer substrates in each of which an interlayer connection conductor has high strength, and circuit modules each including such a resin multilayer substrate.

A resin multilayer substrate according to an example embodiment of the present invention includes at least one resin insulating layer, a first conductor layer stacked on the resin insulating layer, a second conductor layer stacked on the resin insulating layer on a side opposite to the first conductor layer, and an interlayer connection conductor penetrating the resin insulating layer in a stacking direction of the first conductor layer and the second conductor layer and connecting the first conductor layer and the second conductor layer. The interlayer connection conductor includes a first portion and a second portion located closer to the second conductor layer than the first portion. The first portion has lower conductivity than the second portion. The first conductor layer is not in contact with the second portion. The second conductor layer is in contact with the second portion. When viewed in a cross section in a direction perpendicular or substantially perpendicular to the stacking direction, a distance between two corner portions at which a distal end portion of the second portion is most separated in the direction perpendicular or substantially perpendicular to the stacking direction is longer than a distance between two corner portions at which a proximal end portion of the second portion is in contact with the second conductor layer, and a portion of the first portion is closer to the second conductor layer than a straight line connecting the corner portions of the distal end portion of the second portion.

A circuit module according to an example embodiment of the present invention includes a resin multilayer substrate according to an example embodiment of the present invention and an electronic component on the resin multilayer substrate.

According to example embodiments of the present invention, resin multilayer substrates in each of which an interlayer connection conductor has high strength, and circuit modules each including such a resin multilayer substrate are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a cross-sectional view schematically illustrating an example of a resin multilayer substrate according to a first example embodiment of the present invention.

FIGS. 2A to 2F are cross-sectional views schematically illustrating an example of a method for producing a resin multilayer substrate 1 according to an example embodiment of the present invention.

FIG. 3 is a cross-sectional view schematically illustrating an example of a resin multilayer substrate according to a second example embodiment of the present invention.

FIG. 4A is a cross-sectional view schematically illustrating an example of a resin multilayer substrate according to a third example embodiment of the present invention.

FIG. 4B is an example of an SEM photograph showing a cross section of the resin multilayer substrate according to the third example embodiment of the present invention.

FIG. 5 is a cross-sectional view schematically illustrating an example of a resin multilayer substrate according to a fourth example embodiment of the present invention.

FIG. 6 is a cross-sectional view schematically illustrating an example of a resin multilayer substrate according to a fifth example embodiment of the present invention.

FIG. 7 is a cross-sectional view schematically illustrating an example of a resin multilayer substrate according to a sixth example embodiment of the present invention.

FIG. 8 is a cross-sectional view schematically illustrating an example of a circuit module including a resin multilayer substrate according to an example embodiment of the present invention.

### DETAILED DESCRIPTION OF THE EXAMPLE EMBODIMENTS

Example embodiments of the present invention will be described in detail below with reference to the drawings.

Hereinafter, resin multilayer substrates and circuit modules according to example embodiments of the present invention will be described.

However, the present invention is not limited to the following configurations, and changes can be appropriately applied thereto within a range not changing the scope of the present invention. The present invention also includes a combination of two or more of the individual example configurations of the present invention described below.

Each example embodiment of the present invention described below is an example, and partial replacement or combination of configurations illustrated in different example embodiments is possible. In the second and subsequent example embodiments, descriptions of matters common to the first example embodiment will be omitted, and only differences will be described. In particular, the same operations and advantageous effects by the same or substantially the same configurations will not be sequentially described for each example embodiment.

In the present specification, the terms (for example, “vertical”, “parallel”, “orthogonal”, and the like) indicating the relationship between elements and the terms indicating the shape of an element are not expressions indicating only a strict meaning, but are expressions including a substantially equivalent range, for example, a difference of about several %.

The drawings are schematic views, and dimensions, scales of aspect ratios, and the like may be different from those of actual products. In the drawings, the same or corresponding portions are denoted by the same reference numerals. In each drawing, the same elements are denoted by the same reference numerals, and redundant description will be omitted.

### First Example Embodiment

In a resin multilayer substrate according to a first example embodiment of the present invention, an interlayer connection conductor includes a first portion and a second portion, and a first conductor layer is in contact with the first portion.

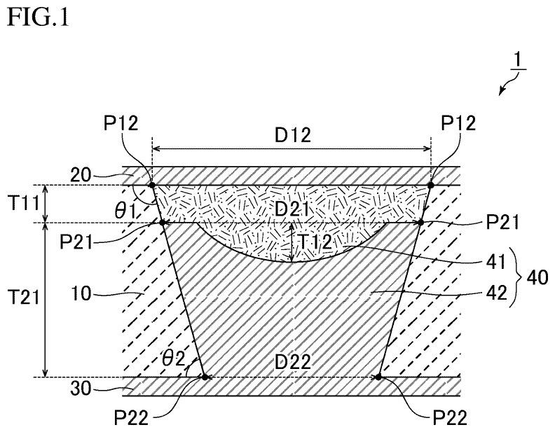

FIG. 1 is a cross-sectional view schematically illustrating an example of the resin multilayer substrate according to the first example embodiment of the present invention.

Although an overall configuration is not illustrated in FIG. 1, the resin multilayer substrate 1 includes at least one resin insulating layer 10, a first conductor layer 20 stacked on the resin insulating layer 10, a second conductor layer 30 stacked on the resin insulating layer 10 on a side (lower side in FIG. 1) opposite to the first conductor layer 20, and an interlayer connection conductor 40 penetrating the resin insulating layer 10 in a stacking direction (vertical direction in FIG. 1) of the first conductor layer 20 and the second conductor layer 30 and connecting the first conductor layer 20 and the second conductor layer 30.

The resin of the resin insulating layer 10 may be, for example, a thermosetting resin or a thermoplastic resin, but is preferably a thermoplastic resin. In a case where the resin insulating layer 10 is made of a thermoplastic resin, a plurality of resin sheets on which the conductor layer is provided can be stacked, and collectively press-bonded by heat treatment.

Examples of the thermosetting resin include an epoxy resin, a phenol resin, a polyimide resin or a modified resin thereof, or an acrylic resin.

Examples of the thermoplastic resin include a liquid crystal polymer (LCP), a fluororesin, a thermoplastic polyimide resin, a polyether ether ketone resin (PEEK), or a polyphenylene sulfide resin (PPS).

The resin insulating layer 10 is preferably made of liquid crystal polymer (LCP), for example. Liquid crystal polymers have lower water absorption than other thermoplastic resins. Therefore, in a case where the resin insulating layer 10 is made of a liquid crystal polymer, moisture remaining in the resin insulating layer 10 can be reduced.

The resin insulating layer 10 may include an inorganic material such as a ceramic filler, for example.

Examples of the ceramic filler include boron nitride, talc, or fused silica.

The thickness (length in the stacking direction) of one layer of the resin insulating layer 10 is, for example, preferably about 10 μm or more and about 100 μm or less.

Each of the first conductor layer 20 and the second conductor layer 30 may have a patterned shape obtained by patterning the layer into lines, for example, or may have a planar shape spread over one surface. The shapes of the first conductor layer 20 and the second conductor layer 30 may be the same as or different from each other.

Each of the first conductor layer 20 and the second conductor layer 30 is a metal layer made of, for example, copper, silver, aluminum, stainless steel, nickel, gold, or an alloy including at least one of these metals. The materials of the first conductor layer 20 and the second conductor layer 30 may be the same as or different from each other. Each of the first conductor layer 20 and the second conductor layer 30 is preferably made of a metal foil, and more preferably made of a copper (Cu) foil, for example.

Each of the first conductor layer 20 and the second conductor layer 30 may have a mat surface on one main surface and a shiny surface on the other main surface.

The thickness (length in the stacking direction) of each of the first conductor layer 20 and the second conductor layer 30 is, for example, preferably about 1 μm or more and about 35 μm or less, and more preferably about 6 μm or more and about 18 μm or less. The thicknesses of the first conductor layer 20 and the second conductor layer 30 may be the same as or different from each other.

The first conductor layer 20 and the second conductor layer 30 may or may not be parallel or substantially parallel to each other.

One resin insulating layer 10 may be provided between the first conductor layer 20 and the second conductor layer 30, or two or more resin insulating layers 10 may be provided between them. In a case where two or more resin insulating layers 10 are provided between the first conductor layer 20 and the second conductor layer 30, the configurations of the resin insulating layers 10 may be the same as or different from each other. In addition, in a case where two or more resin insulating layers 10 are provided between the first conductor layer 20 and the second conductor layer 30, the thickness of the resin insulating layers 10 may be the same as or different from each other.

The interlayer connection conductor 40 is provided so as to be connected to the first conductor layer 20 and the second conductor layer 30 while penetrating the resin insulating layer 10 in the stacking direction but not penetrating the first conductor layer 20 and the second conductor layer 30. Therefore, the interlayer connection conductor 40 penetrates the resin insulating layer(s) 10 in the stacking direction by the number of layers provided between the first conductor layer 20 and the second conductor layer 30.

In a cross section perpendicular substantially perpendicular to the direction, the shape of the interlayer connection conductor 40 is preferably circular. In this case, not only a perfect circle but also an ellipse, an oval, and the like are included in the circle.

The interlayer connection conductor 40 includes a first portion 41 and a second portion 42 located closer to the second conductor layer 30 than the first portion 41.

The first portion 41 has lower conductivity than the second portion 42.

The first portion 41 may be a paste via or a plated via, for example. As described above, the paste via means a paste solidified, and the plated via means a film grown by a liquid phase method or a gas phase method.

In a case where the first portion 41 is a plated via, the first portion 41 preferably does not include resin. For example, in a case where the first portion 41 is a plated via, the content of the conductor in the first portion 41 is preferably about 90.0 vol % or more and about 100 vol % or less.

The second portion 42 may be a paste via or a plated via, but is preferably a plated via, for example.

In a case where the second portion 42 is a plated via, the second portion 42 preferably does not include resin. For example, in a case where the second portion 42 is a plated via, the content of the conductor in the second portion 42 is preferably about 90.0 vol % or more and about 100 vol % or less.

In the present specification, “not including resin” means that the content of the resin is, for example, about 0.1 vol % or less.

In a case where the second portion 42 is a plated via, the conductor of the second portion 42 is preferably the same as the metal of the second conductor layer 30, and is, for example, Cu.

For example, preferably, the first portion 41 is a paste via and the second portion 42 is a plated via. In this case, the content of the resin in the first portion 41 is greater than the content of the resin in the second portion 42. In a case where the resin multilayer substrate 1 is manufactured by collective pressing described later, the first portion 41 defines and functions as a bonding material, so that the second portion 42 and the first conductor layer 20 can be conductively connected.

The type and content of the resin included in the first portion 41 or the second portion 42 can be measured by a method such as, for example, Fourier transform infrared spectroscopy (FT-IR) or gas chromatograph mass spectrometry (GC-MS). The same applies to a third portion 43 described later.

In a case where the first portion 41 is a paste via, examples of the conductor of the first portion 41 include Cu, Sn, Ag, Ni, Cr, Pt, Mo, Ga, Ge, Sb, In, Pb, or an alloy including at least one of these metals. The conductor of the first portion 41 may be the same as or different from the conductor of the second portion 42. The conductor of the first portion 41 is, for example, an alloy including Cu and Sn.

In a case where the first portion 41 is a paste via, examples of the resin of the first portion 41 include at least one thermosetting resin of an epoxy resin, a phenol resin, a polyimide resin or a modified resin thereof, or an acrylic resin, or at least one thermoplastic resin of a polyamide resin, a polystyrene resin, a polymethacrylic resin, a polycarbonate resin, or a cellulose-based resin.

In a case where the first portion 41 is a paste via, the content of the conductor of the first portion 41 is preferably smaller than the content of the conductor of the second portion 42. The content of the conductor in the first portion 41 is preferably greater than the content of the resin in the first portion 41.

The combination of the materials of the first portion 41 and the second portion 42 is not limited. For the first portion 41, an alloy or a metal including resin is preferably used for the purpose of bonding, and on the other hand, for the second portion 42, a pure metal or a material including less resin, alloy, or no resin is preferably used to improve conductivity, for example.

In a case where the first portion 41 is a plated via, examples of the conductor of the first portion 41 include Sn. By using Sn having a low melting point, it is easy to cause the first portion 41 to define and function as a bonding material.

As described above, in a case where the first portion 41 and the second portion 42 are plated vias, for example, a combination of plated vias made of different metals in which the conductor of the first portion 41 is Sn and the conductor of the second portion 42 is Cu may be used.

The first conductor layer 20 is not in contact with the second portion 42. In the example illustrated in FIG. 1, the first conductor layer 20 is in contact with the first portion 41.

The second conductor layer 30 is in contact with the second portion 42. It is preferable that the second conductor layer 30 and the second portion 42 are made of the same material, and are bonded without using different materials.

In the resin multilayer substrate 1 illustrated in FIG. 1, among the end portions of the second portion 42 in the stacking direction (vertical direction in FIG. 1), an end portion on the first conductor layer 20 side is defined as a distal end portion, and an end portion on the second conductor layer 30 side is defined as a proximal end portion. On the other hand, among the end portions of the first portion 41 in the stacking direction, an end portion on the second conductor layer 30 side is defined as a distal end portion, and an end portion on the first conductor layer 20 side is defined as a proximal end portion. In FIG. 1, in the distal end portion of the second portion 42, each portion most separated in the direction perpendicular or substantially perpendicular to the stacking direction (the left-right direction in FIG. 1) is illustrated as a corner portion P21. Further, in FIG. 1, in the proximal end portion of the second portion 42, each portion in contact with the second conductor layer 30 is illustrated as a corner portion P22. Further, in FIG. 1, in the proximal end portion of the first portion 41, each portion in contact with the first conductor layer 20 is illustrated as a corner portion P12.

As illustrated in FIG. 1, when viewed in a cross section in a direction perpendicular or substantially perpendicular to the stacking direction, a distance (length indicated by double-headed arrow D21 in FIG. 1) between the two corner portions P21 at which the distal end portion of the second portion 42 is most separated in the direction perpendicular or substantially perpendicular to the stacking direction is longer than a distance (length indicated by double-headed arrow D22 in FIG. 1) between the two corner portions P22 at which the proximal end portion of the second portion 42 is in contact with the second conductor layer 30, and a portion of the first portion 41 exists closer to the second conductor layer 30 than a straight line connecting the corner portions P21 of the distal end portion of the second portion 42.

In the resin multilayer substrate 1 illustrated in FIG. 1, since the second portion 42 is connected to the first portion 41 so as to wrap the first portion 41 in a recessed shape, the strength of a portion where a reaction product to bond the first portion 41 and the second portion 42 is provided, for example, can be increased, so that the strength of the interlayer connection conductor 40 is increased.

The first portion 41 existing closer to the second conductor layer 30 than the straight line connecting the corner portions P21 of the distal end portion of the second portion 42 may be one as illustrated in FIG. 1, or may be two or more.

When viewed in a cross section in a direction perpendicular or substantially perpendicular to the stacking direction, the distance D21 between the corner portions P21 of the distal end portion of the second portion 42 is, for example, about 60 μm or more and about 80 μm or less.

When viewed in a cross section in a direction perpendicular or substantially perpendicular to the stacking direction, the distance D22 between the corner portions P22 of the proximal end portion of the second portion 42 is, for example, about 40 μm or more and about 60 μm or less.

A ratio of D22/D21 is, for example, about 0.67 or more and about 0.75 or less.

When the maximum thickness in the stacking direction between the straight line connecting the corner portions P21 of the distal end portion of the second portion 42 and the first conductor layer 20 when viewed in a cross section in a direction perpendicular or substantially perpendicular to the stacking direction is denoted by T11, the maximum thickness T11 is, for example, about 5 μm or more and about 15 μm or less.

When the maximum thickness in the stacking direction between the straight line connecting the corner portions P21 of the distal end portion of the second portion 42 and the second conductor layer 30 when viewed in a cross section in a direction perpendicular to the stacking direction is denoted by T21, the maximum thickness T21 is, for example, about 20 μm or more and about 30 μm or less. The maximum thickness T21 is preferably greater than the maximum thickness T11.

When the maximum thickness in the stacking direction between the straight line connecting the corner portions P21 of the distal end portion of the second portion 42 and the end portion of the first portion 41 locating on the second conductor layer 30 side when viewed in a cross section in a direction perpendicular or substantially perpendicular to the stacking direction is denoted by T12, the maximum thickness T12 is, for example, about 1 μm or more and about 10 μm or less. The maximum thickness T12 may be equal or substantially equal to the maximum thickness T11, may be less than the maximum thickness T11, or may be greater than the maximum thickness T11.

A ratio of T12/(T11+T21) is, for example, about 0.03 or more and about 0.29 or less. A ratio of T12/(T11+T12) is, for example, about 0.17 or more and about 0.40 or less. A ratio of T12/T11 is, for example, about 0.2 or more and about 0.6 or less. A ratio of T12/T21 is, for example, about 0.03 or more and about 0.50 or less.

When a cross section of the interlayer connection conductor 40 passing through a straight line connecting the corner portions P21 of the distal end portion of the second portion 42 is viewed from the stacking direction as a cross section from a direction different from that in FIG. 1, an area of the first portion 41 existing closer to the second conductor layer 30 than the straight line connecting the corner portions P21 of the distal end portion of the second portion 42 is, for example, preferably about 10% or more, more preferably about 20% or more, and still more preferably about 50% or more with respect to an area of an entire cross section of the interlayer connection conductor 40 passing through a straight line connecting the corner portions P21 of the distal end portion of the second portion 42. The area of the first portion 41 existing closer to the second conductor layer 30 than the straight line connecting the corner portions P21 of the distal end portion of the second portion 42 may be, for example, about 100%, about 90% or less, or about 80% or less with respect to the area of the entire or substantially the entire cross section of the interlayer connection conductor 40 passing through the straight line connecting the corner portions P21 of the distal end portion of the second portion 42.

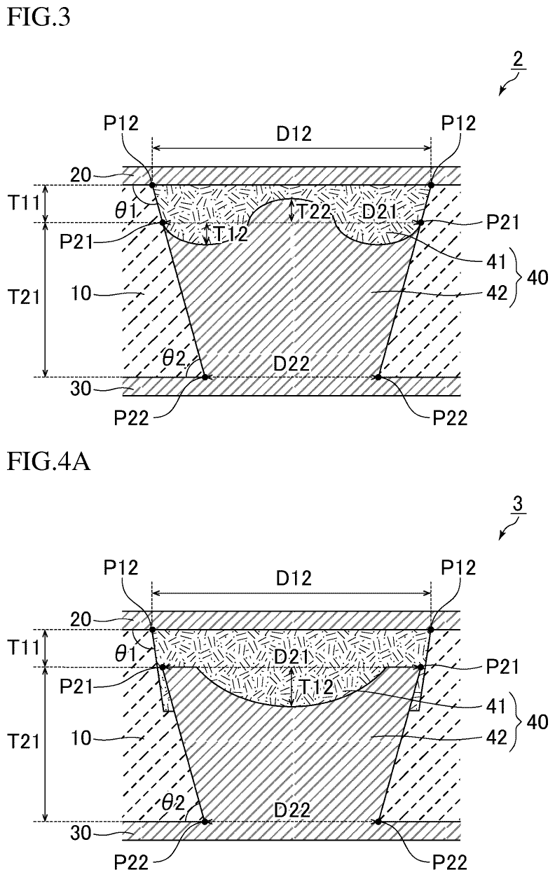

When viewed in a cross section in a direction perpendicular or substantially perpendicular to the stacking direction, the shape of the corner portion P21 of the distal end portion of the second portion 42 is not limited, and for example, may be flat as illustrated in FIG. 1 or may be pointed as illustrated in FIG. 3 to be described later. In a case where the corner portion P21 of the distal end portion of the second portion 42 is flat, the corner portion P21 of the distal end portion of the second portion 42 may or may not be parallel or substantially parallel to the first conductor layer 20 or the second conductor layer 30.

When viewed in a cross section in a direction perpendicular or substantially perpendicular to the stacking direction, the second portion 42 may not exist closer to the first conductor layer 20 than the straight line connecting the corner portions P21 of the distal end portion of the second portion 42.

When viewed in a cross section in a direction perpendicular or substantially perpendicular to the stacking direction, the straight line connecting the corner portions P21 of the distal end portion of the second portion 42 may be parallel or substantially parallel to the second conductor layer 30.

When viewed in a cross section in a direction perpendicular or substantially perpendicular to the stacking direction, an outer angle (angle indicated by θ2 in FIG. 1) between the interlayer connection conductor 40 and the second conductor layer 30 may be an acute angle at the corner portion P22 of the proximal end portion of the second portion 42.

In the example shown in FIG. 1, when viewed in a cross section in a direction perpendicular or substantially perpendicular to the stacking direction, the distance (length indicated by double-headed arrow D21 in FIG. 1) between the corner portions P21 of the distal end portion of the second portion 42 is shorter than the distance (length indicated by double-headed arrow D12 in FIG. 1) between the corner portions P12 of the proximal end portion of the first portion 41, but may be equal or substantially equal to the distance D12 between the corner portions P12 of the proximal end portion of the first portion 41.

When viewed in a cross section in a direction perpendicular or substantially perpendicular to the stacking direction, the distance D12 between the corner portions P12 of the proximal end portion of the first portion 41 is, for example, about 80 μm or more and about 100 μm or less.

A ratio of D12/D21 is, for example, about 1.25 or more and about 1.33 or less. In addition, a ratio of D12/D22 is, for example, about 1.67 or more and about 2 or less.

When viewed in a cross section in a direction perpendicular or substantially perpendicular to the stacking direction, the straight line connecting the corner portions P21 of the distal end portion of the second portion 42 may be parallel or substantially parallel to the first conductor layer 20.

When viewed in a cross section in a direction perpendicular or substantially perpendicular to the stacking direction, at a corner portion P12 of the proximal end portion of the first portion 41, an outer angle (angle indicated by θ1 in FIG. 1) between the interlayer connection conductor 40 and the first conductor layer 20 may be an obtuse angle, an acute angle, or a right angle.

In a case where the resin multilayer substrate 1 illustrated in FIG. 1 includes a plurality of interlayer connection conductors 40, it is sufficient that at least one interlayer connection conductor 40 has the structure illustrated in FIG. 1.

The resin multilayer substrate 1 illustrated in FIG. 1 is manufactured, for example, by the following method.

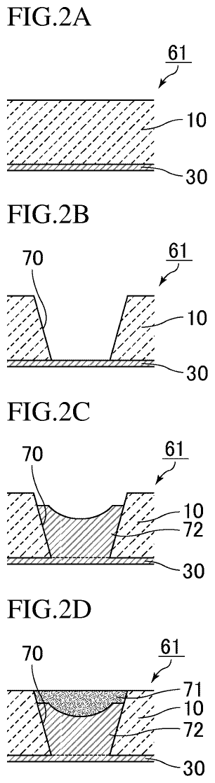

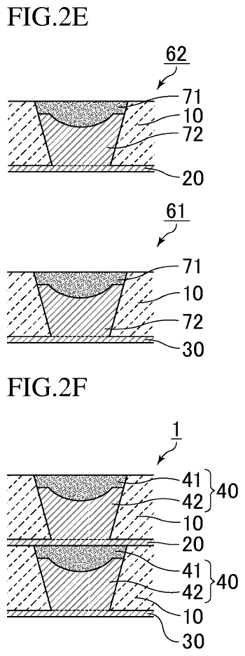

FIGS. 2A to 2F are cross-sectional views schematically illustrating an example of a method for producing a resin multilayer substrate 1 according to an example embodiment of the present invention. The resin multilayer substrate 1 may be manufactured in a state of one chip (individual piece), or may be manufactured by manufacturing a collective board and then separating the collective board into individual pieces. Here, the collective board refers to a board including a plurality of resin multilayer substrates 1.

First, as illustrated in FIG. 2A, a first base 61 in which the second conductor layer 30 is formed on one surface of the resin insulating layer 10 is prepared.

For example, a metal foil such as a Cu foil is laminated on one main surface of the resin insulating layer 10, and the metal foil is patterned by photolithography to form the second conductor layer 30. The resin insulating layer 10 is, for example, a resin sheet including a thermoplastic resin such as a liquid crystal polymer as a main component.

Next, as illustrated in FIG. 2B, a via hole 70 penetrating the resin insulating layer 10 and exposing a portion of the upper surface of the second conductor layer 30 is formed in the first base 61. The via hole 70 preferably has a tapered shape in which the hole diameter decreases toward the second conductor layer 30.

For example, the via hole 70 is formed in the resin insulating layer 10 with a laser, for example, such that the upper surface of the second conductor layer 30 is exposed.

Subsequently, as illustrated in FIG. 2C, the via hole 70 is filled with a second material 72. The via hole 70 is partially filled with the second material 72. The height of the second material 72 is not limited as long as it does not exceed the thickness of the resin insulating layer 10.

For example, the via hole 70 is filled with a plating metal such as Cu as the second material 72 by a plating process such as an electrolytic plating process. The second portion 42 (see FIG. 2F) is formed of the second material 72.

Thereafter, as illustrated in FIG. 2D, a first material 71 is poured into the via hole 70, which has been filled with the second material 72. The space in the via hole 70 is filled with the first material 71 and the second material 72.

For example, the via hole 70, which has been filled with the second material 72 is filled with a conductive paste including a metal material such as Cu or Sn and a resin material as the first material 71. The first material 71 is solidified by the heating press described later to form the first portion 41 (see FIG. 2F).

As illustrated in FIG. 2E, a plurality of bases including the first base 61 filled with the first material 71 and the second material 72 are stacked. FIG. 2E illustrates an example in which the first base 61 filled with the first material 71 and the second material 72, and the second base 62 filled with the first material 71 and the second material 72 are stacked, but is not limited as long as the first base 61 filled with the first material 71 and the second material 72 is included.

Thereafter, as illustrated in FIG. 2F, heat and pressure are applied to press them at once. As a result, the conductive paste is solidified to form the first portion 41, and the first portion 41 and the first conductor layer 20 are bonded to each other, and the first portion 41 and the second portion 42 are bonded to each other.

At this time, the interlayer connection conductor 40 having the structure illustrated in FIG. 1 can be formed by adjusting conditions of plating process, and conditions for forming a via hole, for example.

An example of the composition of the plating solution used in the plating process and the electrolysis conditions will be described below.

### Plating Solution

Cu about 50 g/L
H₂SO₄ about 150 g/L
Cl⁻ about 130 ppm
SPS (bis(3-sulfopropyl) disulfide) about 1 ppm
PEG (polyethylene glycol, average molecular weight about 4000) about 300 ppm
JGB (Janus Green B) about 10 ppm

### Electrolysis Conditions

about 30A/dm²

Through the above steps, the resin multilayer substrate 1 is manufactured.

According to this example of a manufacturing method, the resin multilayer substrate 1 can be easily manufactured by collectively pressing the resin insulating layers 10. Therefore, the manufacturing process of the resin multilayer substrate 1 is reduced, and the manufacturing cost can be reduced.

### Second Example Embodiment

In a resin multilayer substrate according to a second example embodiment of the present invention, when viewed in a cross section in a direction perpendicular or substantially perpendicular to a stacking direction, a portion of a second portion exists closer to a first conductor layer than a straight line connecting the corner portions of a distal end portion of a second portion.

FIG. 3 is a cross-sectional view schematically illustrating an example of the resin multilayer substrate according to the second example embodiment of the present invention.

Although an overall configuration is not illustrated in FIG. 3, a resin multilayer substrate 2 includes at least one resin insulating layer 10, a first conductor layer 20 stacked on the resin insulating layer 10, a second conductor layer 30 stacked on the resin insulating layer 10 on a side (lower side in FIG. 3) opposite to the first conductor layer 20, and an interlayer connection conductor 40 penetrating the resin insulating layer 10 in a stacking direction (vertical direction in FIG. 3) of the first conductor layer 20 and the second conductor layer 30 and connecting the first conductor layer 20 and the second conductor layer 30.

In the resin multilayer substrate 2 illustrated in FIG. 3, when viewed in a cross section in a direction perpendicular or substantially perpendicular to the stacking direction, a distance (length indicated by double-headed arrow D21 in FIG. 3) between two corner portions P21 at which the distal end portion of the second portion 42 is most separated in the direction perpendicular or substantially perpendicular to the stacking direction is longer than a distance (length indicated by double-headed arrow D22 in FIG. 3) between two corner portions P22 at which the proximal end portion of the second portion 42 is in contact with the second conductor layer 30, and a portion of the first portion 41 exists closer to the second conductor layer 30 than a straight line connecting the corner portions P21 of the distal end portion of the second portion 42.

In the resin multilayer substrate 2 illustrated in FIG. 3, similarly to the resin multilayer substrate 1 illustrated in FIG. 1, since the second portion 42 is connected to the first portion 41 so as to wrap the first portion 41 in a recessed shape, the strength of a portion where a reaction product to bond the first portion 41 and the second portion 42 is provided, for example, can be increased, so that the strength of the interlayer connection conductor 40 is increased.

Further, in the resin multilayer substrate 2 illustrated in FIG. 3, when viewed in a cross section in a direction perpendicular or substantially perpendicular to a stacking direction, a portion of the second portion 42 exists closer to the first conductor layer 20 than a straight line connecting the corner portions P21 of the distal end portion of the second portion 42.

In the resin multilayer substrate 2 illustrated in FIG. 3, as compared with the resin multilayer substrate 1 illustrated in FIG. 1, the surface area of the boundary surface between the second portion 42 and the first portion 41 is increased, so that the strength of the interlayer connection conductor 40 is further increased.

The first portion 41 existing closer to the second conductor layer 30 than the straight line connecting the corner portions P21 of the distal end portion of the second portion 42 may be two or more as illustrated in FIG. 3, or may be one.

The second portion 42 existing closer to the first conductor layer 20 than the straight line connecting the corner portions P21 of the distal end portion of the second portion 42 may be one as illustrated in FIG. 3, or may be two or more.

When the maximum thickness in the stacking direction between the straight line connecting the corner portions P21 of the distal end portion of the second portion 42 and the end portion of the second portion 42 locating on the first conductor layer 20 side when viewed in a cross section in a direction perpendicular or substantially perpendicular to the stacking direction is denoted by T22, the maximum thickness T22 is, for example, about 1 μm or more and about 10 μm or less.

The maximum thickness T22 may be equal or substantially equal to the maximum thickness T12, may be greater than the maximum thickness T12, or may be less than the maximum thickness T12.

A ratio of T22/(T11+T21) is, for example, about 0.03 or more and about 0.29 or less. A ratio of T22/(T21+T22) is, for example, about 0.03 or more and about 0.33 or less. A ratio of T22/T11 is, for example, about 0.20 or more and about 0.67 or less. A ratio of T22/T21 is, for example, about 0.2 or more and about 0.6 or less.

When a cross section of the interlayer connection conductor 40 passing through a straight line connecting the corner portions P21 of the distal end portion of the second portion 42 is viewed from the stacking direction as a cross section from a direction different from that in FIG. 3, an area of the first portion 41 existing closer to the second conductor layer 30 than a straight line connecting the corner portions P21 of the distal end portion of the second portion 42 is, for example, preferably about 10% or more, and more preferably about 20% or more with respect to an area of an entire or substantially an entire cross section of the interlayer connection conductor 40 passing through a straight line connecting the corner portions P21 of the distal end portion of the second portion 42. The area of the first portion 41 existing closer to the second conductor layer 30 than the straight line connecting the corner portions P21 of the distal end portion of the second portion 42 may be, for example, about 50% or less with respect to the area of the entire or substantially the entire cross section of the interlayer connection conductor 40 passing through the straight line connecting the corner portions P21 of the distal end portion of the second portion 42.

Similarly, when a cross section of the interlayer connection conductor 40 passing through a straight line connecting the corner portions P21 of the distal end portion of the second portion 42 is viewed from the stacking direction, an area of the second portion 42 existing closer to the first conductor layer 20 than a straight line connecting the corner portions P21 of the distal end portion of the second portion 42 is, for example, preferably about 10% or more, and more preferably about 20% or more with respect to an area of an entire cross section of the interlayer connection conductor 40 passing through a straight line connecting the corner portions P21 of the distal end portion of the second portion 42. The area of the second portion 42 existing closer to the first conductor layer 20 than the straight line connecting the corner portions P21 of the distal end portion of the second portion 42 may be, for example, about 50% or less with respect to the area of the entire cross section of the interlayer connection conductor 40 passing through the straight line connecting the corner portions P21 of the distal end portion of the second portion 42.

The ratio of the area of the second portion 42 existing closer to the first conductor layer 20 than the straight line connecting the corner portions P21 of the distal end portion of the second portion 42 may be equal or substantially equal to the ratio of the area of the first portion 41 existing closer to the second conductor layer 30 than the straight line connecting the corner portions P21 of the distal end portion of the second portion 42, may be greater than the ratio of the area of the first portion 41 existing closer to the second conductor layer 30 than the straight line connecting the corner portions P21 of the distal end portion of the second portion 42, or may be smaller than the ratio of the area of the first portion 41 existing closer to the second conductor layer 30 than the straight line connecting the corner portions P21 of the distal end portion of the second portion 42.

When viewed in a cross section in a direction perpendicular or substantially perpendicular to the stacking direction, the shape of the corner portion P21 of the distal end portion of the second portion 42 is not limited, and for example, may be pointed as illustrated in FIG. 3 or may be flat as illustrated in FIG. 1 described above. In a case where the corner portion P21 of the distal end portion of the second portion 42 is flat, the corner portion P21 of the distal end portion of the second portion 42 may or may not be parallel or substantially parallel to the first conductor layer 20 or the second conductor layer 30.

In a case where the resin multilayer substrate 2 illustrated in FIG. 3 includes a plurality of interlayer connection conductors 40, it is sufficient that at least one interlayer connection conductor 40 has the structure illustrated in FIG. 3.

Other configurations are common with those of the first example embodiment.

### Third Example Embodiment

In a resin multilayer substrate according to a third example embodiment of the present invention, when viewed in a cross section in a direction perpendicular or substantially perpendicular to the stacking direction, a first portion covers at least one of corner portions of a distal end portion of a second portion so as to wrap around a portion of at least one side surface of the second portion.

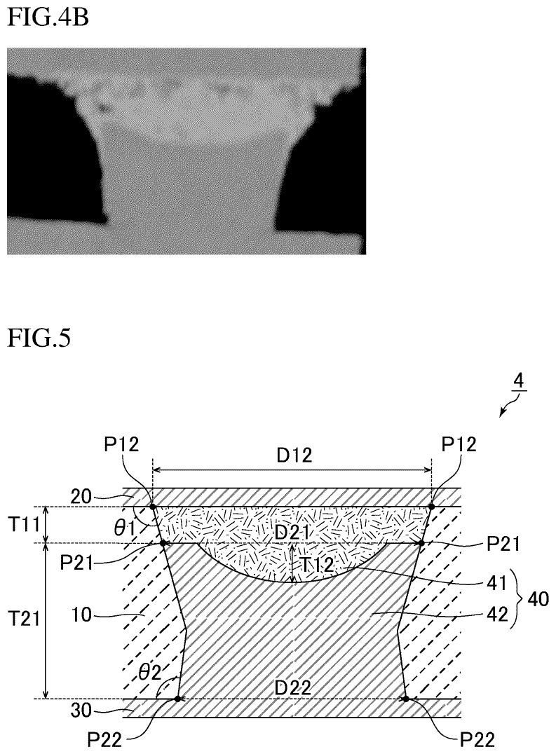

FIG. 4A is a cross-sectional view schematically illustrating an example of the resin multilayer substrate according to the third example embodiment of the present invention. FIG. 4B is an example of an SEM photograph showing a cross section of the resin multilayer substrate according to the third example embodiment of the present invention.

Although an overall configuration is not illustrated in FIG. 4A, a resin multilayer substrate 3 includes at least one resin insulating layer 10, a first conductor layer 20 stacked on the resin insulating layer 10, a second conductor layer 30 stacked on the resin insulating layer 10 on a side (lower side in FIG. 4A) opposite to the first conductor layer 20, and an interlayer connection conductor 40 penetrating the resin insulating layer 10 in a stacking direction (vertical direction in FIG. 4A) of the first conductor layer 20 and the second conductor layer 30 and connecting the first conductor layer 20 and the second conductor layer 30.

In the resin multilayer substrate 3 illustrated in FIG. 4A, when viewed in a cross section in a direction perpendicular or substantially perpendicular to the stacking direction, a distance (length indicated by double-headed arrow D21 in FIG. 4A) between two corner portions P21 at which the distal end portion of the second portion 42 is most separated in the direction perpendicular or substantially perpendicular to the stacking direction is longer than a distance (length indicated by double-headed arrow D22 in FIG. 4A) between two corner portion P22 at which the proximal end portion of the second portion 42 is in contact with the second conductor layer 30, and a portion of the first portion 41 exists closer to the second conductor layer 30 than a straight line connecting the corner portions P21 of the distal end portion of the second portion 42.

In the resin multilayer substrate 3 illustrated in FIG. 4A, similarly to the resin multilayer substrate 1 illustrated in FIG. 1, since the second portion 42 is connected to the first portion 41 so as to wrap the first portion 41 in a recessed shape, the strength of a portion where a reaction product to bond the first portion 41 and the second portion 42 is provided, for example, can be increased, so that the strength of the interlayer connection conductor 40 is increased.

Further, in the resin multilayer substrate 3 illustrated in FIG. 4A, when viewed in a cross section in a direction perpendicular or substantially perpendicular to the stacking direction, the first portion 41 covers the corner portion P21 of the distal end portion of the second portion 42 so as to wrap around a portion of at least one side surface of the second portion 42. The first portion 41 may cover at least a portion of the corner portions P21 of the distal end portion of the second portion 42.

In the resin multilayer substrate 3 illustrated in FIG. 4A, since the first portion 41 covers the corner portion P21 of the distal end portion of the second portion 42, the strength of the interlayer connection conductor 40 is further increased as compared with the resin multilayer substrate 1 illustrated in FIG. 1.

In a case where the resin multilayer substrate 3 illustrated in FIG. 4A includes a plurality of interlayer connection conductors 40, it is sufficient that at least one interlayer connection conductor 40 has the structure illustrated in FIG. 4A.

Other configurations are common with those of the first example embodiment or the second example embodiment.

### Fourth Example Embodiment

In a resin multilayer substrate according to a fourth example embodiment of the present invention, when viewed in a cross section in a direction perpendicular or substantially perpendicular to the stacking direction, an outer angle between an interlayer connection conductor and a second conductor layer is an obtuse angle at at least one of corner portions of a proximal end portion of a second portion.

FIG. 5 is a cross-sectional view schematically illustrating an example of the resin multilayer substrate according to the fourth example embodiment of the present invention.

Although an overall configuration is not illustrated in FIG. 5, a resin multilayer substrate 4 includes at least one resin insulating layer 10, a first conductor layer 20 stacked on the resin insulating layer 10, a second conductor layer 30 stacked on the resin insulating layer 10 on a side (lower side in FIG. 5) opposite to the first conductor layer 20, and an interlayer connection conductor 40 penetrating the resin insulating layer 10 in a stacking direction (vertical direction in FIG. 5) of the first conductor layer 20 and the second conductor layer 30 and connecting the first conductor layer 20 and the second conductor layer 30.

In the resin multilayer substrate 4 illustrated in FIG. 5, when viewed in a cross section in a direction perpendicular or substantially perpendicular to the stacking direction, a distance (length indicated by double-headed arrow D21 in FIG. 5) between two corner portions P21 at which the distal end portion of the second portion 42 is most separated in the direction perpendicular or substantially perpendicular to the stacking direction is longer than a distance (length indicated by double-headed arrow D22 in FIG. 5) between two corner portions P22 at which the proximal end portion of the second portion 42 is in contact with the second conductor layer 30, and a portion of the first portion 41 exists closer to the second conductor layer 30 than a straight line connecting the corner portions P21 of the distal end portion of the second portion 42.

In the resin multilayer substrate 4 illustrated in FIG. 5, similarly to the resin multilayer substrate 1 illustrated in FIG. 1, since the second portion 42 is connected to the first portion 41 so as to wrap the first portion 41 in a recessed shape, the strength of a portion where a reaction product to bond the first portion 41 and the second portion 42 is provided, for example, can be increased, so that the strength of the interlayer connection conductor 40 is increased.

Further, in the resin multilayer substrate 4 illustrated in FIG. 5, when viewed in a cross section in a direction perpendicular or substantially perpendicular to the stacking direction, an outer angle (angle indicated by θ2 in FIG. 5) between the interlayer connection conductor 40 and the second conductor layer 30 is an obtuse angle at the corner portion P22 of the proximal end portion of the second portion 42. As illustrated in FIG. 5, the second portion 42 includes a constricted portion between the distal end portion and the proximal end portion. At least a portion of the outer angle θ2 between the interlayer connection conductor 40 and the second conductor layer 30 may be an obtuse angle.

In the resin multilayer substrate 4 illustrated in FIG. 5, since the outer angle θ2 between the interlayer connection conductor 40 and the second conductor layer 30 is an obtuse angle, the area of the bonding portion between the second portion 42 and the second conductor layer 30 can be increased, so that the strength of the interlayer connection conductor 40 is further increased as compared with the resin multilayer substrate 1 illustrated in FIG. 1.

In a case where the resin multilayer substrate 4 illustrated in FIG. 5 includes a plurality of interlayer connection conductors 40, it is sufficient that at least one interlayer connection conductor 40 has the structure illustrated in FIG. 5.

Other configurations are common with any of the first to third example embodiments.

### Fifth Example Embodiment

In a resin multilayer substrate according to a fifth example embodiment of the present invention, an interlayer connection conductor further includes a third portion, and a first conductor layer is in contact with the third portion. Thus, the line density can be increased.

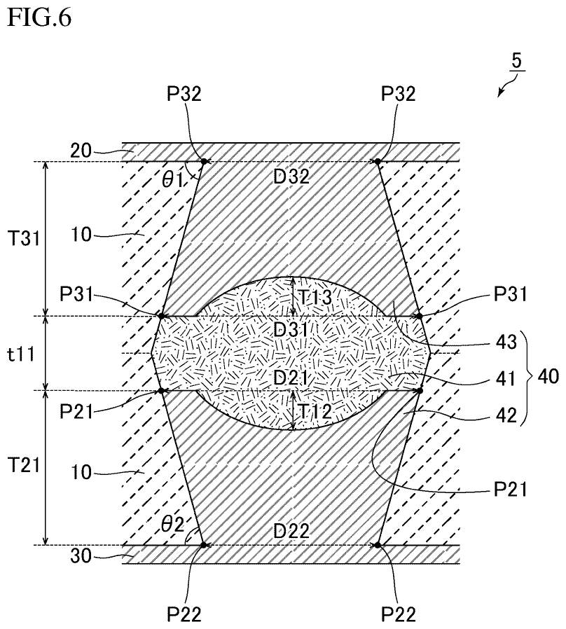

FIG. 6 is a cross-sectional view schematically illustrating an example of the resin multilayer substrate according to the fifth example embodiment of the present invention.

Although an overall configuration is not illustrated in FIG. 6, a resin multilayer substrate 5 includes at least two resin insulating layers 10, a first conductor layer 20 stacked on the resin insulating layer 10, a second conductor layer 30 stacked on the resin insulating layer 10 on a side (lower side in FIG. 6) opposite to the first conductor layer 20, and an interlayer connection conductor 40 penetrating the resin insulating layer 10 in a stacking direction (vertical direction in FIG. 6) of the first conductor layer 20 and the second conductor layer 30 and connecting the first conductor layer 20 and the second conductor layer 30.

Two resin insulating layers 10 may be provided between the first conductor layer 20 and the second conductor layer 30, or three or more resin insulating layers 10 may be provided between them. The configurations of the resin insulating layers 10 may be the same as or different from each other. The thicknesses of the resin insulating layers 10 may be the same as or different from each other.

In the illustrated in FIG. 6, one resin insulating layer 10 is provided on the first conductor layer 20 side, and one resin insulating layer 10 is provided on the second conductor layer 30 side. In FIG. 6, the boundary between the resin insulating layers 10 is indicated by a broken line. It is sufficient that at least one resin insulating layer 10 is provided on the first conductor layer 20 side, and at least one resin insulating layer 10 is provided on the second conductor layer 30 side. The number of resin insulating layers 10 provided on the first conductor layer 20 side may be the same as or different from the number of resin insulating layers 10 provided on the second conductor layer 30 side.

The interlayer connection conductor 40 includes a first portion 41 and a second portion 42 located closer to the second conductor layer 30 than the first portion 41.

The first portion 41 and the second portion 42 are the same as or similar to those of the first example embodiment.

The interlayer connection conductor 40 further includes a third portion 43 located closer to the first conductor layer 20 than the first portion 41.

The first portion 41 has lower conductivity than the third portion 43.

The third portion 43 may be, for example, a paste via or a plated via, but is preferably a plated via.

In a case where the third portion 43 is a plated via, the third portion 43 preferably does not include resin. For example, in a case where the third portion 43 is a plated via, the content of the conductor in the third portion 43 is preferably about 90.0 vol % or more and about 100 vol % or less.

In a case where the third portion 43 is a plated via, the conductor of the third portion 43 is preferably the same as the metal of the first conductor layer 20, and is, for example, Cu. The conductor of the third portion 43 may be the same as or different from the conductor of the second portion 42.

For example, preferably, the first portion 41 is a paste via and the second portion 42 and the third portion 43 are plated vias. In this case, the content of the resin in the first portion 41 is greater than the content of the resin in the second portion 42 and the third portion 43. In a case where the resin multilayer substrate 5 is manufactured by collective pressing, the first portion 41 defines and functions as a bonding material, so that the second portion 42 and the third portion 43 can be conductively connected.

In a case where the first portion 41 is a paste via, the conductor of the first portion 41 may be the same as or different from the conductors of the second portion 42 and the third portion 43. The conductor of the first portion 41 is, for example, an alloy including Cu and Sn.

The combination of the materials of the first portion 41, the second portion 42, and the third portion 43 is not limited. For the first portion 41, an alloy or a metal including resin is preferably used for the purpose of bonding, and on the other hand, for the second portion 42 and the third portion 43, a pure metal or a material including less resin, alloy, or no resin is preferably used to improve conductivity, for example.

In a case where the first portion 41, the second portion 42 and the third portion 43 are plated vias, for example, a combination of plated vias made of different metals in which the conductor of the first portion 41 is Sn and the conductor of the second portion 42 and the third portion 43 is Cu may be used.

The first conductor layer 20 is not in contact with the second portion 42. In the example illustrated in FIG. 6, the first conductor layer 20 is in contact with the third portion 43. It is preferable that the first conductor layer 20 and the third portion 43 are made of the same material, and are bonded without using different materials.

The second conductor layer 30 is in contact with the second portion 42. It is preferable that the second conductor layer 30 and the second portion 42 are made of the same material, and are bonded without using different materials.

In the resin multilayer substrate 5 illustrated in FIG. 6, when viewed in a cross section in a direction perpendicular or substantially perpendicular to the stacking direction, a distance (length indicated by double-headed arrow D21 in FIG. 6) between two corner portions P21 at which the distal end portion of the second portion 42 is most separated in the direction perpendicular or substantially perpendicular to the stacking direction is longer than a distance (length indicated by double-headed arrow D22 in FIG. 6) between two corner portions P22 at which the proximal end portion of the second portion 42 is in contact with the second conductor layer 30, and a portion of the first portion 41 exists closer to the second conductor layer 30 than a straight line connecting the corner portions P21 of the distal end portion of the second portion 42.

In the resin multilayer substrate 5 illustrated in FIG. 6, similarly to the resin multilayer substrate 1 illustrated in FIG. 1, since the second portion 42 is connected to the first portion 41 so as to wrap the first portion 41 in a recessed shape, the strength of a portion where a reaction product to bond the first portion 41 and the second portion 42 is provided, for example, can be increased, so that the strength of the interlayer connection conductor 40 is increased.

In the resin multilayer substrate 5 illustrated in FIG. 6, among the end portions of the third portion 43 in the stacking direction (vertical direction in FIG. 6), an end portion on the second conductor layer 30 side is defined as a distal end portion, and an end portion on the first conductor layer 20 side is defined as a proximal end portion. In FIG. 6, in the distal end portion of the third portion 43, each portion most separated in the direction perpendicular or substantially perpendicular to the stacking direction (the left-right direction in FIG. 6) is illustrated as a corner portion P31. Further, in FIG. 6, in the proximal end portion of the third portion 43, each portion in contact with the first conductor layer 20 is illustrated as a corner portion P32.

As illustrated in FIG. 6, when viewed in a cross section in a direction perpendicular or substantially perpendicular to the stacking direction, a distance (length indicated by double-headed arrow D31 in FIG. 6) between the two corner portions P31 at which the distal end portion of the third portion 43 is most separated in the direction perpendicular or substantially perpendicular to the stacking direction may be longer than a distance (length indicated by double-headed arrow D32 in FIG. 6) between the two corner portions P32 at which the proximal end portion of the third portion 43 is in contact with the first conductor layer 20, and a portion of the first portion 41 may exist closer to the first conductor layer 20 than a straight line connecting the corner portions P31 of the distal end portion of the third portion 43.

In the resin multilayer substrate 5 illustrated in FIG. 6, when the third portion 43 is connected to the first portion 41 so as to wrap the first portion 41 in a recessed shape, the strength of a portion where a reaction product to bond the second portion 42 and the third portion 43 is provided, for example, can be increased, so that the strength of the interlayer connection conductor 40 is further increased.

The first portion 41 existing closer to the second conductor layer 30 than the straight line connecting the corner portions P21 of the distal end portion of the second portion 42 may be one as illustrated in FIG. 6, or may be two or more.

The first portion 41 existing closer to the first conductor layer 20 than the straight line connecting the corner portions P31 of the distal end portion of the third portion 43 may be one as illustrated in FIG. 6, or may be two or more.

When viewed in a cross section in a direction perpendicular or substantially perpendicular to the stacking direction, the distance D21 between the corner portions P21 of the distal end portion of the second portion 42 is, for example, about 60 μm or more and about 80 μm or less.

When viewed in a cross section in a direction perpendicular or substantially perpendicular to the stacking direction, the distance D22 between the corner portions P22 of the proximal end portion of the second portion 42 is, for example, about 40 μm or more and about 60 μm or less.

A ratio of D22/D21 is, for example, about 0.67 or more and about 0.75 or less.

When viewed in a cross section in a direction perpendicular or substantially perpendicular to the stacking direction, the distance D31 between the corner portions P31 of the distal end portion of the third portion 43 is, for example, about 60 μm or more and about 80 μm or less. The value of D31 may be equal to or different from the value of D21.

When viewed in a cross section in a direction perpendicular to the stacking direction, the distance D32 between the corner portions P32 of the proximal end portion of the third portion 43 is, for example, about 40 μm or more and about 60 μm or less. The value of D32 may be equal to or different from the value of D22.

A ratio of D32/D31 is, for example, about 0.67 or more and about 0.75 or less. The value of D32/D31 may be equal to or different from the value of D22/D21.

When the maximum thickness in the stacking direction between the straight line connecting the corner portions P21 of the distal end portion of the second portion 42 and the straight line connecting the corner portions P31 of the distal end portion of the third portion 43 when viewed in a cross section in a direction perpendicular or substantially perpendicular to the stacking direction is denoted by t11, the maximum thickness t11 is, for example, about 10 μm or more and about 30 μm or less.

When the maximum thickness in the stacking direction between the straight line connecting the corner portions P21 of the distal end portion of the second portion 42 and the second conductor layer 30 when viewed in a cross section in a direction perpendicular or substantially perpendicular to the stacking direction is denoted by T21, the maximum thickness T21 is, for example, about 20 μm or more and about 30 μm or less. The maximum thickness T21 is, for example, preferably greater than about half of the maximum thickness t11 (i.e., t11/2).

When the maximum thickness in the stacking direction between the straight line connecting the corner portions P21 of the distal end portion of the second portion 42 and the end portion of the first portion 41 locating on the second conductor layer 30 side when viewed in a cross section in a direction perpendicular or substantially perpendicular to the stacking direction is denoted by T12, the maximum thickness T12 is, for example, about 1 μm or more and about 10 μm or less. The maximum thickness T12 may be equal or substantially equal to half of the maximum thickness t11, smaller than half of the maximum thickness t11, or greater than half of the maximum thickness t11.

A ratio of T12/((t11/2)+T21) is, for example, about 0.03 or more and about 0.29 or less. A ratio of T12/((t11/2)+T12) is, for example, about 0.17 or more and about 0.40 or less. A ratio of T12/(t11/2) is, for example, about 0.2 or more and about 0.6 or less. A ratio of T12/T21 is, for example, about 0.03 or more and about 0.50 or less.

When the maximum thickness in the stacking direction between the straight line connecting the corner portions P31 of the distal end portion of the third portion 43 and the first conductor layer 20 when viewed in a cross section in a direction perpendicular or substantially perpendicular to the stacking direction is denoted by T31, the maximum thickness T31 is, for example, about 20 μm or more and about 30 μm or less. The maximum thickness T31 is, for example, preferably greater than half of the maximum thickness t11. The value of T31 may be equal to or different from the value of T21.

When the maximum thickness in the stacking direction between the straight line connecting the corner portions P31 of the distal end portion of the third portion 43 and the end portion of the first portion 41 locating on the first conductor layer 20 side when viewed in a cross section in a direction perpendicular or substantially perpendicular to the stacking direction is denoted by T13, the maximum thickness T13 is, for example, about 1 μm or more and about 10 μm or less. The maximum thickness T13 may be equal or substantially equal to half of the maximum thickness t11, smaller than half of the maximum thickness t11, or greater than half of the maximum thickness t11. The value of T13 may be equal to or different from the value of T12.

A ratio of T13/((t11/2)+T31) is, for example, about 0.03 or more and about 0.29 or less. The value of T13/((t11/2)+T31) may be equal to or different from the value of T12/((t11/2)+T21). A ratio of T13/((t11/2)+T13) is, for example, about 0.17 or more and about 0.40 or less. The value of T13/((t11/2)+T13) may be equal to or different from the value of T12/((t11/2)+T12). A ratio of T13/(t11/2) is, for example, about 0.2 or more and about 0.6 or less. The value of T13/(t11/2) may be equal to or different from the value of T12/(t11/2). A ratio of T13/T31 is, for example, about 0.03 or more and about 0.50 or less. The value of T13/T31 may be equal to or different from the value of T12/T21.

When a cross section of the interlayer connection conductor 40 passing through a straight line connecting the corner portions P21 of the distal end portion of the second portion 42 is viewed from the stacking direction as a cross section from a direction different from that in FIG. 6, an area of the first portion 41 existing closer to the second conductor layer 30 than the straight line connecting the corner portions P21 of the distal end portion of the second portion 42 is, for example, preferably about 10% or more, more preferably about 20% or more, and still more preferably about 50% or more with respect to an area of an entire or substantially an entire cross section of the interlayer connection conductor 40 passing through a straight line connecting the corner portions P21 of the distal end portion of the second portion 42. The area of the first portion 41 existing closer to the second conductor layer 30 than the straight line connecting the corner portions P21 of the distal end portion of the second portion 42 may be, for example, about 100%, about 90% or less, or about 80% or less with respect to the area of the entire or substantially the entire cross section of the interlayer connection conductor 40 passing through the straight line connecting the corner portions P21 of the distal end portion of the second portion 42.

Further, when a cross section of the interlayer connection conductor 40 passing through a straight line connecting the corner portions P31 of the distal end portion of the third portion 43 is viewed from the stacking direction, an area of the first portion 41 existing closer to the first conductor layer 20 than the straight line connecting the corner portions P31 of the distal end portion of the third portion 43 is, for example, preferably about 10% or more, more preferably about 20% or more, and still more preferably about 50% or more with respect to an area of an entire cross section of the interlayer connection conductor 40 passing through a straight line connecting the corner portions P31 of the distal end portion of the third portion 43. The area of the first portion 41 existing closer to the first conductor layer 20 than the straight line connecting the corner portions P31 of the distal end portion of the third portion 43 may be, for example, about 100%, about 90% or less, or about 80% or less with respect to the area of the entire or substantially the entire cross section of the interlayer connection conductor 40 passing through the straight line connecting the corner portions P31 of the distal end portion of the third portion 43.

The ratio of the area of the first portion 41 existing closer to the first conductor layer 20 than the straight line connecting the corner portions P31 of the distal end portion of the third portion 43 may be equal or substantially equal to the ratio of the area of the first portion 41 existing closer to the second conductor layer 30 than the straight line connecting the corner portions P21 of the distal end portion of the second portion 42, may be greater than the ratio of the area of the first portion 41 existing closer to the second conductor layer 30 than the straight line connecting the corner portions P21 of the distal end portion of the second portion 42, and may be smaller than the ratio of the area of the first portion 41 existing closer to the second conductor layer 30 than the straight line connecting the corner portions P21 of the distal end portion of the second portion 42.

When viewed in a cross section in a direction perpendicular or substantially perpendicular to the stacking direction, the shape of the corner portion P21 of the distal end portion of the second portion 42 is not limited, and for example, may be flat as illustrated in FIG. 6 or may be pointed as illustrated in FIG. 3 described above. In a case where the corner portion P21 of the distal end portion of the second portion 42 is flat, the corner portion P21 of the distal end portion of the second portion 42 may or may not be parallel or substantially parallel to the first conductor layer 20 or the second conductor layer 30.

When viewed in a cross section in a direction perpendicular or substantially perpendicular to the stacking direction, the second portion 42 may not exist closer to the first conductor layer 20 than the straight line connecting the corner portions P21 of the distal end portion of the second portion 42, or a portion of the second portion 42 may exist closer to the first conductor layer 20 than the straight line connecting the corner portions P21 of the distal end portion of the second portion 42.

When viewed in a cross section in a direction perpendicular or substantially perpendicular to the stacking direction, the straight line connecting the corner portions P21 of the distal end portion of the second portion 42 may be parallel or substantially parallel to the second conductor layer 30.

When viewed in a cross section in a direction perpendicular or substantially perpendicular to the stacking direction, at a corner portion P22 of the proximal end portion of the second portion 42, an outer angle (angle indicated by θ2 in FIG. 6) between the interlayer connection conductor 40 and the second conductor layer 30 may be an acute angle, an obtuse angle, or a right angle.

When viewed in a cross section in a direction perpendicular or substantially perpendicular to the stacking direction, the shape of the corner portion P31 of the distal end portion of the third portion 43 is not limited, and for example, may be flat as illustrated in FIG. 6 or may be pointed as illustrated in FIG. 3 described above. In a case where the corner portion P31 of the distal end portion of the third portion 43 is flat, the corner portion P31 of the distal end portion of the third portion 43 may or may not be parallel or substantially parallel to the first conductor layer 20 or the second conductor layer 30.

When viewed in a cross section in a direction perpendicular or substantially perpendicular to the stacking direction, the third portion 43 may not exist closer to the second conductor layer 30 than the straight line connecting the corner portions P31 of the distal end portion of the third portion 43, or a portion of the third portion 43 may exist closer to the second conductor layer 30 than the straight line connecting the corner portions P31 of the distal end portion of the third portion 43.

When viewed in a cross section in a direction perpendicular or substantially perpendicular to the stacking direction, the straight line connecting the corner portions P31 of the distal end portion of the third portion 43 may be parallel or substantially parallel to the first conductor layer 20.

When viewed in a cross section in a direction perpendicular or substantially perpendicular to the stacking direction, at a corner portion P32 of the proximal end portion of the third portion 43, an outer angle (angle indicated by θ1 in FIG. 6) between the interlayer connection conductor 40 and the first conductor layer 20 may be an acute angle, an obtuse angle, or a right angle.

In a case where the resin multilayer substrate 5 illustrated in FIG. 6 includes a plurality of interlayer connection conductors 40, it is sufficient that at least one interlayer connection conductor 40 has the structure illustrated in FIG. 6.

Other configurations are common with any of the first to fourth example embodiments.

The resin multilayer substrate 5 illustrated in FIG. 6 is manufactured, for example, by a method similar to that in FIGS. 2A to 2F. At this time, the interlayer connection conductor 40 having the structure illustrated in FIG. 6 can be formed by overlapping the first base 61 and the second base 62 such that the first materials 71 face each other.

### Sixth Example Embodiment

In a resin multilayer substrate according to a sixth example embodiment of the present invention, when viewed in a cross section in direction a perpendicular or substantially perpendicular to a stacking direction, a straight line connecting the corner portions of a distal end portion of a second portion is not parallel or substantially parallel to a second conductor layer.

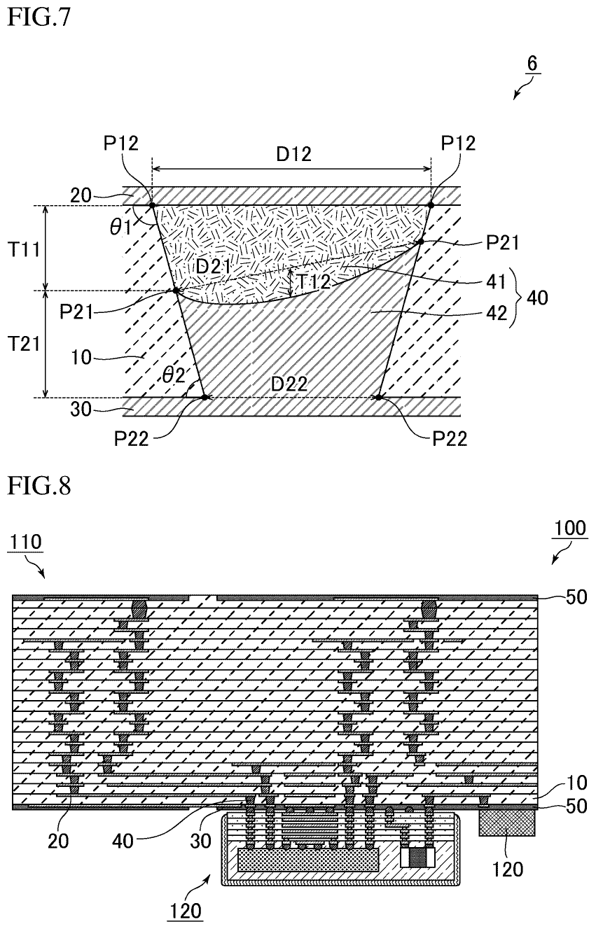

FIG. 7 is a cross-sectional view schematically illustrating an example of the resin multilayer substrate according to the sixth example embodiment of the present invention.

As in the resin multilayer substrate 6 illustrated in FIG. 7, when viewed in a cross section in a direction perpendicular or substantially perpendicular to the stacking direction, a straight line connecting corner portions P21 of a distal end portion of a second portion 42 may not be parallel or substantially parallel to a second conductor layer 30. Also in the resin multilayer substrate 6 illustrated in FIG. 7, the same or substantially the same advantageous effects as those of the resin multilayer substrate 1 illustrated in FIG. 1 can be obtained.

In a case where the resin multilayer substrate 6 illustrated in FIG. 7 includes a plurality of interlayer connection conductors 40, it is sufficient that at least one interlayer connection conductor 40 has the structure illustrated in FIG. 7.

Other configurations are common with any of the first to fifth example embodiments.

For example, in a case where the interlayer connection conductor 40 includes the third portion 43 as in the resin multilayer substrate 5 illustrated in FIG. 6 described in the fifth example embodiment, when viewed in a cross section in a direction perpendicular or substantially perpendicular to the stacking direction, a straight line connecting the corner portions P21 of the distal end portion of the second portion 42 is not parallel or substantially parallel to the second conductor layer 30, and a straight line connecting the corner portions P31 of the distal end portion of the third portion 43 may or may not be parallel or substantially parallel to the first conductor layer 20. Alternatively, the straight line connecting the corner portions P31 of the distal end portion of the third portion 43 is not parallel or substantially parallel to the first conductor layer 20, and the straight line connecting the corner portions P21 of the distal end portion of the second portion 42 may or may not be parallel or substantially parallel to the second conductor layer 30.

### Other Example Embodiments

The resin multilayer substrate of the present invention is not limited to the above example embodiments, and various applications and modifications can be made within the scope of the present invention with respect to the configuration, manufacturing conditions, and the like of the resin multilayer substrate.

For example, an alloy layer with a composition different from that of both the first portion and the second portion may be provided on at least a portion of an interface between the first portion and the second portion of the interlayer connection conductor. When the alloy layer is provided at the interface between the first portion and the second portion, the connectivity between the first portion and the second portion is improved. The alloy layer may include one layer or two or more layers.

The alloy layer provided at the interface between the first portion and the second portion of the interlayer connection conductor can be confirmed, for example, by observing a cross section obtained by cutting the resin insulating layer in a direction parallel or substantially parallel to the thickness direction using a scanning electron microscope (SEM). Since the alloy layer is different in composition from both the first portion and the second portion, the alloy layer is displayed in a color tone different from those of the first portion and the second portion in the SEM photograph.

Even when the kinds of included metal elements are the same, the case where the content ratios of the respective metal elements are different is also considered as being “different in composition”. For example, the compositions of Cu₅Sn, Cu₃Sn, Cu₆Sn₅, and the like are all compositions including Cu and Sn as metal species, but the compositions are different from each other because the content ratios of the metal species are different.

Similarly, in a case where the interlayer connection conductor further includes the third portion, an alloy layer having a composition different from that of both the first portion and the third portion may be provided on at least a portion of an interface between the first portion and the third portion of the interlayer connection conductor. When the alloy layer is provided at the interface between the first portion and the third portion, the connectivity between the first portion and the third portion is improved. The alloy layer may include one layer or two or more layers.

In a case where the first portion of the interlayer connection conductor is in contact with the first conductor layer, an alloy layer having a composition different from that of both the first portion and the first conductor layer may be provided on at least a portion of an interface between the first portion of the interlayer connection conductor and the first conductor layer. When the alloy layer is provided at the interface between the first portion and the first conductor layer, the connectivity between the first portion and the first conductor layer is improved. The alloy layer may include one layer or two or more layers.

In a case where a resin multilayer substrate according to an example embodiment of the present invention includes a plurality of interlayer connection conductors, it is sufficient that at least one interlayer connection conductor has the structure according to an example embodiment of the present invention. In addition, a resin multilayer substrate according to an example embodiment of the present invention may include two or more kinds of interlayer connection conductors having the structure described in one example embodiment and interlayer connection conductors having the structure described in another example embodiment.

In a case where a resin multilayer substrate according to an example embodiment of the present invention includes a plurality of interlayer connection conductors, for example, an interlayer connection conductor including a plated via or an interlayer connection conductor including a paste via may be included.

A resin multilayer substrate according to an example embodiment of the present invention may include an insulating layer different from the resin insulating layer provided between the first conductor layer and the second conductor layer. For example, the resin multilayer substrate according to an example embodiment of the present invention may include a resin insulating layer or a ceramic insulating layer having a dielectric constant different from that of the resin insulating layer provided between the first conductor layer and the second conductor layer. In this case, the dielectric constant is preferably higher than that of the resin insulating layer provided between the first conductor layer and the second conductor layer.

A resin multilayer substrate according to an example embodiment of the present invention may be a rigid substrate or a flexible substrate. In a case where the resin multilayer substrate is a flexible substrate, the flexible substrate may include a bent portion.

Resin multilayer substrates according to example embodiments of the present invention can be used, for example, as a board for a circuit module. Such a circuit module is also an example embodiment of the present invention.

FIG. 8 is a cross-sectional view schematically illustrating an example of a circuit module including a resin multilayer substrate according to an example embodiment of the present invention.

A circuit module 100 illustrated in FIG. 8 includes a resin multilayer substrate 110 and an electronic component 120 disposed on the resin multilayer substrate 110.

The resin multilayer substrate 110 is a resin multilayer substrate according to an example embodiment of the present invention. The resin multilayer substrate 110 may be a rigid substrate or a flexible substrate. The resin multilayer substrate 110 may include a bent portion.

The electronic component 120 is not limited, and may be an integrated circuit (IC) or a connector, for example. One or two or more electronic components 120 may be provided on one of the main surfaces of the resin multilayer substrate 110, and one or two or more electronic components 120 may be provided on both main surfaces of the resin multilayer substrate 110.

As illustrated in FIG. 8, the interlayer connection conductor 40 including the first portion and the second portion (both not illustrated) described in the first example embodiment, for example, is preferably provided inside the resin insulating layer 10 located on the surface layer of the resin multilayer substrate 110 on the side (lower side in FIG. 8) where the electronic component 120 is provided. This makes it possible to ensure the connectivity of the interlayer connection conductors even in the fine line portion located on the surface layer.

As described above, in a case where the electronic components 120 are disposed on both main surfaces of the resin multilayer substrate 110, the interlayer connection conductor 40 including the first portion and the second portion is preferably provided inside the resin insulating layer 10 located on both surface layers of the resin multilayer substrate 110.

In a case where the plurality of interlayer connection conductors 40 are provided inside the resin insulating layer 10 located on the surface layer of the resin multilayer substrate 110 on the side where the electronic component 120 is provided, at least one interlayer connection conductor 40 may include the first portion and the second portion, or all of the interlayer connection conductors 40 may include the first portion and the second portion.

The interlayer connection conductor 40 provided inside the resin insulating layer 10 located on the surface layer of the resin multilayer substrate 110 on the side where the electronic component 120 is not provided may be configured to include the first portion and the second portion, may be configured to include only a plated via, may be configured to include only a paste via, or may be configured to include a mixture of these.

Similarly, the interlayer connection conductor 40 provided inside the resin insulating layer 10 located on the inner layer of the resin multilayer substrate 110 may be configured to include the first portion and the second portion, may be configured to include only a plated via, may be configured to include only a paste via, or may be configured to include a mixture of these.

A protective layer 50 may be provided on the surface layer of the resin multilayer substrate 110. The protective layer 50 is a coverlay or a resist layer, for example. The protective layer 50 may be provided on both main surfaces of the resin multilayer substrate 110, or may be provided on one of the main surfaces.

The circuit module of the present invention is not limited to the above example embodiments, and various applications and modifications can be made within the scope of the present invention with respect to the configuration, manufacturing conditions, and the like of the resin multilayer substrate and the electronic component.

The following content is disclosed in the present specification.

<1>

A resin multilayer substrate including at least one resin insulating layer, a first conductor layer stacked on the resin insulating layer, a second conductor layer stacked on the resin insulating layer on a side opposite to the first conductor layer, and an interlayer connection conductor penetrating the resin insulating layer in a stacking direction of the first conductor layer and the second conductor layer and connecting the first conductor layer and the second conductor layer, wherein the interlayer connection conductor includes a first portion and a second portion located closer to the second conductor layer than the first portion, the first portion has lower conductivity than the second portion, the first conductor layer is not in contact with the second portion, the second conductor layer is in contact with the second portion, and when viewed in cross section in a direction perpendicular or substantially perpendicular to the stacking direction, a distance between two corner portions at which a distal end portion of the second portion is most separated in the direction perpendicular or substantially perpendicular to the stacking direction is longer than a distance between two corner portions at which a proximal end portion of the second portion is in contact with the second conductor layer, and a portion of the first portion is closer to the second conductor layer than a straight line connecting the corner portions of the distal end portion of the second portion.

<2>

The resin multilayer substrate according to <1>, wherein when viewed in a cross section in the direction perpendicular or substantially perpendicular to the stacking direction, a portion of the second portion is closer to the first conductor layer than a straight line connecting the corner portions of the distal end portion of the second portion.

<3>

The resin multilayer substrate according to <1> or <2>, wherein when viewed in a cross section in the direction perpendicular or substantially perpendicular to the stacking direction, the first portion covers at least one of the corner portions of the distal end portion of the second portion so as to wrap around a portion of at least one side surface of the second portion.

<4>

The resin multilayer substrate according to any one of <1> to <3>, wherein when viewed in a cross section in the direction perpendicular or substantially perpendicular to the stacking direction, an outer angle between the interlayer connection conductor and the second conductor layer is an obtuse angle at at least one of the corner portions of the proximal end portion of the second portion.

<5>

The resin multilayer substrate according to any one of <1> to <4>, wherein the first conductor layer is in contact with the first portion.

<6>

The resin multilayer substrate according to any one of <1> to <4>, wherein the interlayer connection conductor further includes a third portion located closer to the first conductor layer than the first portion, the first portion has lower conductivity than the third portion, and the first conductor layer is in contact with the third portion.

<7>

The resin multilayer substrate according to <6>, wherein when viewed in a cross section in the direction perpendicular or substantially perpendicular to a stacking direction, a distance between two corner portions at which a distal end portion of the third portion is most separated in the direction perpendicular or substantially perpendicular to the stacking direction is longer than a distance between two corner portions at which a proximal end portion of the third portion is in contact with the first conductor layer, and a portion of the first portion is closer to the first conductor layer than a straight line connecting the corner portions of the distal end portion of the third portion.

<8>

A circuit module including the resin multilayer substrate according to any one of <1> to <7>, and an electronic component on the resin multilayer substrate.

<9>

The circuit module according to <8>, wherein the interlayer connection conductor including the first portion and the second portion is provided inside the resin insulating layer located on a surface layer of the resin multilayer substrate on the side where the electronic component is provided.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A resin multilayer substrate comprising:
at least one resin insulating layer;
a first conductor layer stacked on the resin insulating layer;
a second conductor layer stacked on the resin insulating layer on a side opposite to the first conductor layer; and
an interlayer connection conductor penetrating the resin insulating layer in a stacking direction of the first conductor layer and the second conductor layer and connecting the first conductor layer and the second conductor layer; wherein
the interlayer connection conductor includes a first portion and a second portion located closer to the second conductor layer than the first portion;
the first portion has lower conductivity than the second portion;
the first conductor layer is not in contact with the second portion;
the second conductor layer is in contact with the second portion; and
when viewed in cross section in a direction perpendicular or substantially perpendicular to the stacking direction, a distance between two corner portions at which a distal end portion of the second portion is most separated in the direction perpendicular or substantially perpendicular to the stacking direction is longer than a distance between two corner portions at which a proximal end portion of the second portion is in contact with the second conductor layer, and a portion of the first portion is closer to the second conductor layer than a straight line connecting the corner portions of the distal end portion of the second portion.

2. The resin multilayer substrate according to claim 1, wherein when viewed in a cross section in the direction perpendicular or substantially perpendicular to the stacking direction, a portion of the second portion is closer to the first conductor layer than a straight line connecting the corner portions of the distal end portion of the second portion.

3. The resin multilayer substrate according to claim 1, wherein when viewed in a cross section in the direction perpendicular or substantially perpendicular to the stacking direction, the first portion covers at least one of the corner portions of the distal end portion of the second portion so as to wrap around a portion of at least one side surface of the second portion.

4. The resin multilayer substrate according to claim 1, wherein when viewed in a cross section in the direction perpendicular or substantially perpendicular to the stacking direction, an outer angle between the interlayer connection conductor and the second conductor layer is an obtuse angle at at least one of the corner portions of the proximal end portion of the second portion.

5. The resin multilayer substrate according to claim 1, wherein the first conductor layer is in contact with the first portion.

6. The resin multilayer substrate according to claim 1, wherein
the interlayer connection conductor further includes a third portion located closer to the first conductor layer than the first portion;
the first portion has lower conductivity than the third portion; and
the first conductor layer is in contact with the third portion.

7. The resin multilayer substrate according to claim 6, wherein when viewed in a cross section in the direction perpendicular or substantially perpendicular to a stacking direction, a distance between two corner portions at which a distal end portion of the third portion is most separated in the direction perpendicular or substantially perpendicular to the stacking direction is longer than a distance between two corner portions at which a proximal end portion of the third portion is in contact with the first conductor layer, and a portion of the first portion is closer to the first conductor layer than a straight line connecting the corner portions of the distal end portion of the third portion.

8. The resin multilayer substrate according to claim 1, wherein the resin insulating layer includes an epoxy resin, a phenol resin, a polyimide resin or a modified resin thereof, or an acrylic resin.

9. The resin multilayer substrate according to claim 1, wherein the resin insulating layer includes a liquid crystal polymer, a fluororesin, a thermoplastic polyimide resin, a polyether ether ketone resin, or a polyphenylene sulfide resin.

10. The resin multilayer substrate according to claim 1, wherein a thickness of the resin insulating layer is about 10 μm or more and about 100 μm or less.

11. A circuit module comprising:
the resin multilayer substrate according to claim 1; and
an electronic component on the resin multilayer substrate.

12. The circuit module according to claim 11, wherein the interlayer connection conductor including the first portion and the second portion is provided inside the resin insulating layer located on a surface layer of the resin multilayer substrate on the side where the electronic component is provided.

13. The circuit module according to claim 11, wherein when viewed in a cross section in the direction perpendicular or substantially perpendicular to the stacking direction, a portion of the second portion is closer to the first conductor layer than a straight line connecting the corner portions of the distal end portion of the second portion.

14. The circuit module according to claim 11, wherein when viewed in a cross section in the direction perpendicular or substantially perpendicular to the stacking direction, the first portion covers at least one of the corner portions of the distal end portion of the second portion so as to wrap around a portion of at least one side surface of the second portion.

15. The circuit module according to claim 11, wherein when viewed in a cross section in the direction perpendicular or substantially perpendicular to the stacking direction, an outer angle between the interlayer connection conductor and the second conductor layer is an obtuse angle at at least one of the corner portions of the proximal end portion of the second portion.

16. The circuit module according to claim 11, wherein the first conductor layer is in contact with the first portion.

17. The circuit module according to claim 11, wherein
the interlayer connection conductor further includes a third portion located closer to the first conductor layer than the first portion;
the first portion has lower conductivity than the third portion; and
the first conductor layer is in contact with the third portion.

18. The circuit module according to claim 17, wherein when viewed in a cross section in the direction perpendicular or substantially perpendicular to a stacking direction, a distance between two corner portions at which a distal end portion of the third portion is most separated in the direction perpendicular or substantially perpendicular to the stacking direction is longer than a distance between two corner portions at which a proximal end portion of the third portion is in contact with the first conductor layer, and a portion of the first portion is closer to the first conductor layer than a straight line connecting the corner portions of the distal end portion of the third portion.

19. The circuit module according to claim 11, wherein the resin insulating layer includes an epoxy resin, a phenol resin, a polyimide resin or a modified resin thereof, or an acrylic resin.

20. The circuit module according to claim 11, wherein the resin insulating layer includes a liquid crystal polymer, a fluororesin, a thermoplastic polyimide resin, a polyether ether ketone resin, or a polyphenylene sulfide resin.
